(19) United States
(12) Patent Application Publication
(10) Pub. No.: US 2016/0328163 A1
(43) Pub. Date: Nov. 10, 2016

(54) MEMORY MODULE, MODULE CONTROLLER OF MEMORY MODULE, AND OPERATION METHOD OF MEMORY MODULE

(71) Applicant: SK hynix Inc., Gyeonggi-do (KR)

(72) Inventor: Hyun-Ju YOON, Gyeonggi-do (KR)

(21) Appl. No.: 14/855,132

(22) Filed: Sep. 15, 2015

(30) Foreign Application Priority Data
May 7, 2015 (KR) 10-2015-0063584

(51) Int. Cl. G06F 3/06; G06F 12/08; G11C 14/00

(52) U.S. Cl. CPC G06F 3/0619; G11C 14/0009; G06F 3/0647; G06F 3/0685; G06F 12/0802; G06F 2212/1032; G06F 2212/205

(57) ABSTRACT

An operation method for a memory module that includes communicating with a host; receiving a backup command from the host; reading a setting value of a volatile memory and storing the read setting value as a first storage value; setting a setting value suitable for a backup operation in the volatile memory; performing the backup operation by storing data stored in the volatile memory in a non-volatile memory; setting the first storage value in the volatile memory; and resuming communication with the host.

### CROSS-REFERENCE TO RELATED APPLICATION

The present application claims priority of Korean Patent Application No. 10-2015-0063584, filed on May 7, 2015, which is herein incorporated by reference in its entirety.

### BACKGROUND

1. Field

Exemplary embodiments of the present invention relate to a memory module, the module controller of the memory module and an operation method of the memory module.

2. Description of the Related Art

In general, in a data processing system, such as a personal computer (PC), a workstation, a server computer, or a communication system, a memory module including a plurality of memory chips which have been mounted on a module board, is utilized as memory for storing data.

Memory chips mounted on most memory modules used in data processing systems are volatile memory for example, DRAM. Volatile memory is capable of high speed operation, but has a characteristic in which data is lost upon interruption of a power supply. In order to prevent the data loss of the volatile memory, a memory module using a non-volatile dial in line memory module (NVDIMM) has recently emerged. The non-volatile memory together with volatile memory is mounted on the NVDIMM. In such a memory module during a power supply failure of a host, data loss is prevented by backing up the data of the volatile memory to the non-volatile memory using an auxiliary power supply.

### SUMMARY

Various embodiments are directed to a memory module including a non-volatile memory which is capable of backing up and restoring data of a volatile memory, and an operation method of the memory module.

In an embodiment, an operation method of a memory module including volatile memory, non-volatile memory, and a module controller may include: communicating, by the volatile memory, with a host; receiving, by the module controller, a backup command from the host; reading by the module controller, a setting value of the volatile memory and storing the read setting value as a first storage value; setting, by the module controller, a setting value suitable for a backup operation in the volatile memory; performing, by the module controller, the backup operation by storing data stored in the volatile memory in the non-volatile memory; setting, by the module controller, the first storage value in the volatile memory; and resuming, by the volatile memory, the communication with the host.

The memory module may further include a register suitable for buffering a command and address from the host and transferring the command and address to the volatile memory. The operation method may further include reading, by the module controller, a setting value of the register and storing the read setting value as a second storage value; and setting, by the module controller, the setting value suitable for the backup operation in the register between the receiving of the backup command and the performing of the backup operation.

The operation method may further include setting, by the module controller, the second storage value in the register between the performing of the backup operation and the resuming of the communication.

After the resuming of the communication the operation method may further include receiving a restoration command from the host; setting, by the module controller, a setting value suitable for a restoration operation in the volatile memory; performing, by the module controller, the restoration operation by storing data stored in the non-volatile memory in the volatile memory; and setting by the module controller, the first storage value in the volatile memory.

In an embodiment, a memory module may include a volatile memory; a non-volatile memory; and a module controller suitable for: reading a setting value of the volatile memory in response to a backup command from a host; storing the read setting value as a first storage value; setting a setting value suitable for a backup operation in the volatile memory; performing the backup operation by storing data of the volatile memory in the non-volatile memory; and setting the first storage value in the volatile memory after the backup operation is completed.

The module controller in response to a response to a restoration command from the host may be further suitable for: setting a setting value suitable for a restoration operation in the volatile memory; performing the restoration operation by storing the data of the non-volatile memory to the volatile memory; and setting the first storage value in the volatile memory after the restoration operation is completed.

The memory module may further include a register suitable for buffering a command and address from the host and transferring the command and address to the volatile memory. The module controller in response to the backup command is further suitable for: reading a setting value of the register, and storing the read setting value as a second storage value; setting the value suitable for the backup operation in the register; and setting the second storage value in the register after the backup operation is completed. The memory module controller in response to the restoration command may be further suitable for: setting the value suitable for the restoration operation in the register; and setting the second storage value in the register after the restoration operation is completed.

In an embodiment a module controller of a memory module may include a volatile memory interface; a non-volatile memory interface; a setting value storage unit; and a control logic suitable for: reading a setting value of a volatile memory through the volatile memory interface in response to a backup command from a host; storing the read setting value in the setting value storage unit as a first storage value; setting a value suitable for a backup operation in the volatile memory through the volatile memory interface; performing the backup operation by reading data of the volatile memory through the volatile memory interface and storing the read data in a non-volatile memory through the non-volatile memory interface; and setting the first storage value stored in the setting value storage unit in the volatile memory through the volatile memory interface after the backup operation is completed.

The module controller may further include a system management bus reception unit; and a system management bus transmission unit. The control logic response to the backup command may be further suitable for: reading a setting value of a register through the system management bus reception unit; storing the read setting value in the setting value storage unit as a second storage value; and setting the second storage value stored in the setting value storage unit in the register through the system management bus transmission unit after the backup operation is completed.

The control logic in response to the restoration command may be further suitable for setting a value suitable for the restoration operation in the volatile memory through the volatile memory interface; setting the value suitable for the restoration operation in the register through the system management bus transmission unit; reading the data of the non-volatile memory through the non-volatile memory interface; storing the read data in the volatile memory through the volatile memory interface; setting the first storage value stored in the setting value storage unit in the volatile memory through the volatile memory interface after the restoration operation is completed; and setting the second storage value stored in the setting value storage unit in the register through the system management bus transmission unit.

In an embodiment, an operation method of a memory module comprising a volatile memory unit and a non-volatile memory unit, may include: keeping a setting value for a normal operation of the volatile memory unit; setting the volatile memory unit as suitable for a backup operation; performing the backup operation by transferring data from the volatile memory unit to the non-volatile memory unit, setting the volatile memory unit as suitable for the normal operation by using the kept setting value.

In an embodiment, an operation method of a memory module comprising a volatile memory unit and a non-volatile memory unit, may include: keeping a setting value for a normal operation of the volatile memory unit; setting the volatile memory unit as suitable for a restoration operation; performing the restoration operation by transferring backed-up data from the non-volatile memory unit to the volatile memory unit; and setting the volatile memory unit as suitable for the normal operation by using the kept setting value.

In an embodiment, a memory module may include: a volatile memory unit; a non-volatile memory unit; and a module controller suitable for: keeping a setting value for a normal operation of the volatile memory unit; setting the volatile memory unit as suitable for a backup operation; performing the backup operation by transferring data from the volatile memory unit to the non-volatile memory unit; and setting the volatile memory unit as suitable for the normal operation by using the kept setting value.

The volatile memory unit may include: one or more volatile memories; and a register suitable for buffering and transferring commands and data between an external and the volatile memories. The module controller may include: a volatile memory interface suitable for transferring commands and data between the module controller and the volatile memories; a non-volatile memory interface suitable for transferring commands and data between the module controller and the non-volatile memory unit; a setting value storage unit suitable for keeping the setting value for the normal operation; and a system management bus unit suitable for transferring command and data between the module controller and the register.

In an embodiment, a memory module may include: a volatile memory unit; a non-volatile memory unit; and a module controller suitable for: keeping a setting value for a normal operation of the volatile memory unit; setting the volatile memory unit as suitable for a restoration operation; performing the restoration operation by transferring backed-up data from the non-volatile memory unit to the volatile memory unit; and setting the volatile memory unit as suitable for the normal operation by using the kept setting value.

### BRIEF DESCRIPTION OF THE DRAWINGS

FIG. 1 is a block diagram illustrating a memory module in accordance with an embodiment of the present invention.

FIG. 2 is a block diagram illustrating a module controller shown in FIG. 1.

FIG. 3 is a flowchart illustrating a backup operation of a memory module shown in FIG. 1.

FIG. 4 is a flowchart illustrating a restoration operation of a memory module shown in FIG. 1.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. Throughout the disclosure, like reference numerals refer to like parts throughout the various figures and embodiments of the present invention.

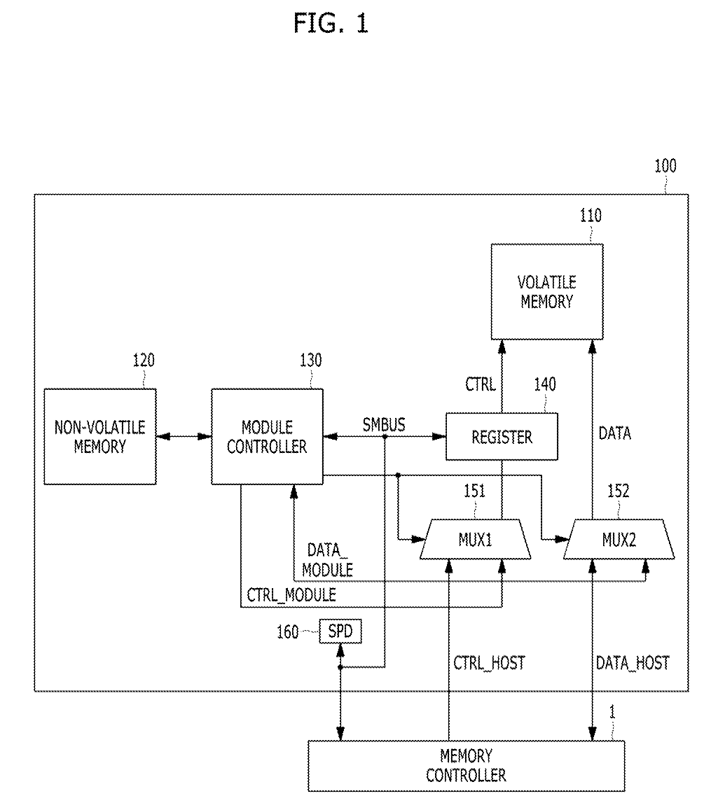

FIG. 1 is a block diagram illustrating a memory module 100 in accordance with an embodiment of the present invention.

Referring to FIG. 1, the memory module 100 may include volatile memory 110, non-volatile memory 120, a module controller 130, a register 140, a first multiplexer 151, a second multiplexer 152, and a serial presence detector (SPD) 160. FIG. 1 also shows a memory controller 1 of a host.

Commands, addresses, and clocks for controlling the volatile memory 110 may be transferred from the memory controller 1 and the module controller 130 through the control buses CTRL_HOST and CTRL_MODULE, respectively. Read data and write data of the volatile memory 110 may be transferred to the memory controller 1 and the module controller 130 through the data buses DATA_HOST and DATA_MODULE, respectively.

The first multiplexer 151 may couple the memory controller 1 to the register 140 through the control bus CTRL_HOST during a normal operation, and couple the module controller 130 to the register 140 through the control bus CTRL_MODULE during a backup operation or a restoration operation. The first multiplexer 151 may be operative under the control of the module controller 130. The second multiplexer 152 may couple the memory controller 1 to the volatile memory 110 through the data bus DATA_HOST during the normal operation, and couple the module controller 130 to the volatile memory 110 through the data bus DATA_MODULE of during the backup operation or the restoration operation. The second multiplexer 152 may be operative under the control of the module controller 130.

The normal operation may represent data communication between the volatile memory 110 and the memory controller 1. The backup operation may represent data transfer from the volatile memory 110 to the non-volatile memory 120. The restoration operation may represent data transfer from the non-volatile memory 120 to the volatile memory 110.

The register 140 may buffer a signal provided from the memory controller 1 and the module controller 130 through the first multiplexer 151, and provide the buffered signal to the volatile memory 110. The register 140 may be a register clock driver (RCD).

The volatile memory 110 may be controlled by a control signal CTRL buffered by the register 140, and may perform data communication with the memory controller 1 and the module controller 130 through a data bus DATA and the second multiplexer 152. As a result, the volatile memory 110 may communicate with the memory controller 1 during the normal operation, and may communicate with the module controller 130 during the backup operation or the restoration operation. The volatile memory 110 may be a DRAM. FIG. 1 exemplarily shows a single piece of the volatile memory 110, a number of which may vary according to a design.

The non-volatile memory 120 may communicate with the module controller 130 during the backup and restoration operations, and may perform read and write operations under the control of the module controller 130. The ion-volatile memory 120 may be a NAND flash, to which the present invention will not be limited. The non-volatile memory 120 may be one or more of all types of non-volatile memory, for example, NOR flash, resistive RAM (RRAM), phase RAM (PRAM), magnetic RAM (MRAM), and spin transfer torque MRAM (STT-MRAM). FIG. 1 exemplarily shows a single piece of the non-volatile memory 120, a number of which may vary according to a design.

The SPD 160 may store information about the memory module 100, for example, information about a type and capacity of memory included in the memory module 100. Furthermore, the SPD 160 may transfer the information about the memory module 100 to the memory controller 1 through a system management bus SMBUS which couples the memory controller 1 with the SPD 160, the memory controller 1 with the module controller 130, and the module controller 130 with the register 140.

The module controller 130 may control the backup and restoration operations in response to backup and restoration commands provided from the memory controller 1 through the system management bus SMBUS, respectively.

During the backup operation, the module controller 130 may set the volatile memory 110 and the register 140 as suitable for the backup operation, and may control the data transfer from the volatile memory 110 to the non-volatile memory 120. After the data transfer, the module controller 130 may set the volatile memory 110 and the register 140 as suitable for the normal operation, and may terminate the backup operation.

During the restoration operation, the module controller 130 may set the volatile memory 110 and the register 140 as suitable for the restoration operation, and may control the data transfer from the non-volatile memory 120 to the volatile memory 110. After the data transfer, the module controller 130 may set the volatile memory 110 and the register 140 as suitable for the normal operation, and may terminate the backup operation.

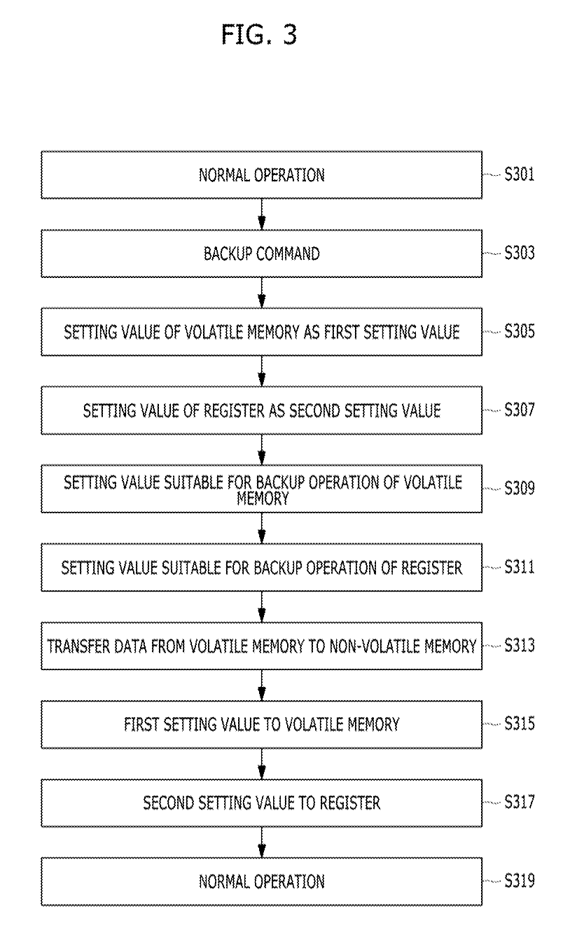

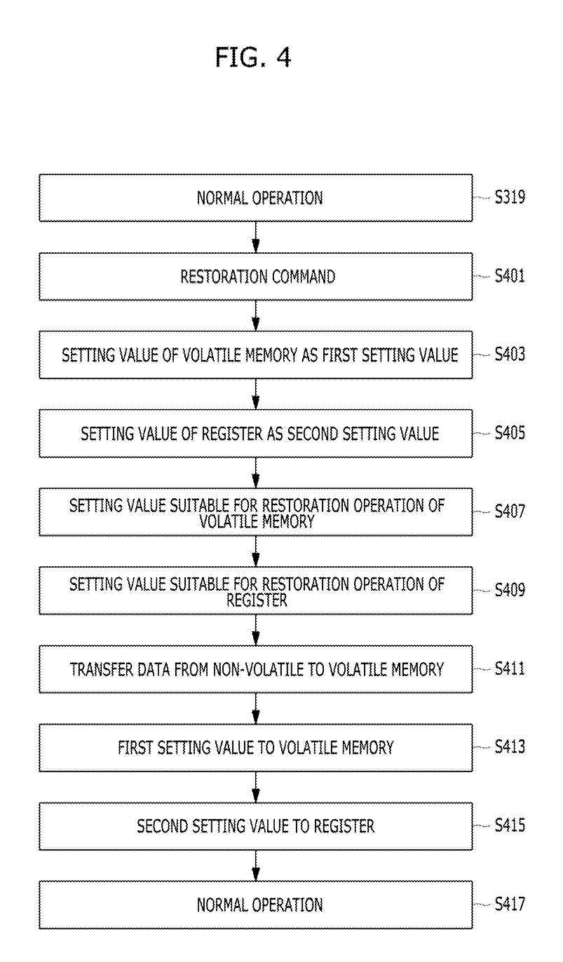

The backup and restoration operations of the memory module 100 will be described with reference to FIGS. 3 to 4.

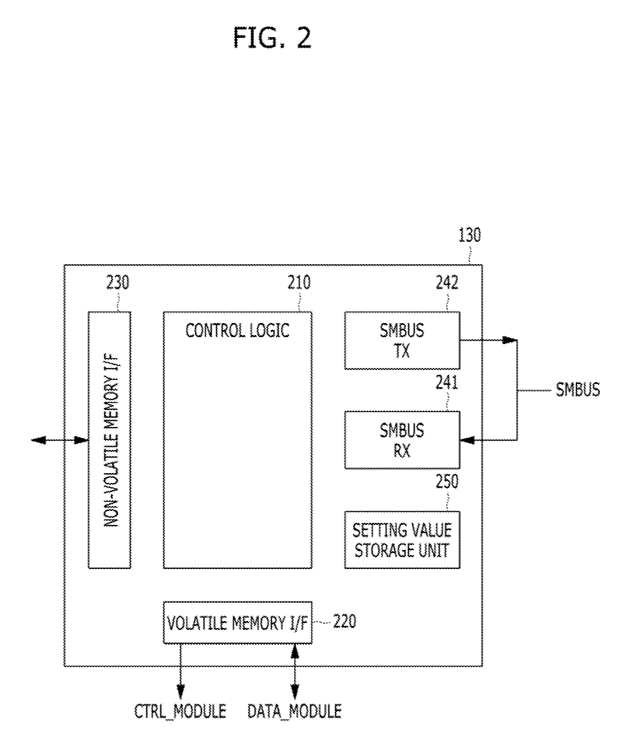

FIG. 2 is a block diagram illustrating the module controller 130 shown in FIG. 1.

Referring to FIG. 2, the module controller 130 may include control logic 210, a volatile memory interface (I/F) 220, a non-volatile memory I/F 230, a system management bus reception (SMBUS RX) unit 241, a system management bus transmission (SMBUS TX) unit 242, and a setting value storage unit 250.

The volatile memory I/F 220 may be an interface for communication with the volatile memory 110. When the volatile memory 110 is DRAM, the volatile memory I/F 220 may comply with the JEDEC standard.

The non-volatile memory I/F 230 may be an interface for communication with the non-volatile memory 120. When the non-volatile memory 120 is NAND flash, the non-volatile memory I/F 230 may comply with one or more of various flash memory standards.

The SMBUS RX unit 241 may receive information from the memory controller 1 and the register 140 through the system management bus SMBUS. For example, the SMBUS RX unit 241 may receive the backup and restoration commands from the memory controller 1 through the system management bus SMBUS. Also, the SMBUS RX unit 241 may receive setting information of the register 140 from the register 140 through the system management bus SMBUS. The SMBUS TX unit 242 may send information to the register 140 through the system management bus SMBUS. For example, the module controller 130 may send setting information of the register 140 to the register 140 through the system management bus SMBUS.

The setting value storage unit 250 may store setting values of the volatile memory 110 and the register 140 for the normal operation during the backup and restoration operations.

The control logic 210 may control the volatile memory I/F 220, the non-volatile memory I/F 230, the SMBUS RX unit 241, the SMBUS TX unit 242, and the setting value storage unit 250 for the backup and restoration operations.

FIG. 3 is a flowchart illustrating the backup operation of the memory module 130 shown in FIG. 1.

Referring to FIG. 3, at step S301 during the normal operation, the memory controller 1 and the volatile memory 110 may communicate with each other. The volatile memory 110 may perform operations such as read and write operations under the control of the memory controller 1.

At step S303, the memory controller 1 may provide the backup command for the backup operation to the module controller 130 through the system management bus SMBUS.

At step S305, the module controller 130 in response to the backup command may read the setting value of the volatile memory 110, and store the read setting value in the setting value storage unit 250 as a first setting value. The first setting value may include values of various timing parameters and voltages for the normal operation of the volatile memory 110 such as write latency and read latency. The module controller 130 may provide the volatile memory 110 with a command to read a mode register set (MRS) value through the control bus CTRL_MODULE, and may receive the setting value of the volatile memory 110 through the data bus DATA_MODULE.

At step S307, the module controller 130 may read the setting value of the register 140, and store the read setting value in the setting value storage unit 250 as a second setting value. The second setting value may include values of various timing parameters and voltages for the normal operation of the register 140. The module controller 130 may provide a configuration resister read command to the register 140 through the system management bus SMBUS, and may receive the setting value of the register 140 through the system management bus SMBUS.

At step S309, the module controller 130 may set the setting values for the volatile memory 110 such that the volatile memory 110 is suitable for the backup operation. During the normal operation, the volatile memory 110 may communicate with the memory controller 1 at high speed. In contrast, during the backup operation, the data may be transferred from the volatile memory 110 to the non-volatile memory 120, and thus the volatile memory 110 may work at low speed in order to step with the non-volatile memory 120 since the non-volatile memory 120 works at lower speed than the volatile memory 120. Therefore, during the backup operation, the various timing parameters and voltages of the volatile memory 110 need to be set according to the low speed operation of the non-volatile memory 120. Such setting may be performed at step S309. The module controller 130 may perform the setting of the volatile memory 110 for the backup operation by providing an MRS command and a setting value to the volatile memory 110 through the control bus CTRL_MODULE, the first multiplexer 151, and the register 140.

At step S311 the module controller 130 may set the setting value for the register 140 such that the register 140 is suitable for the backup operation. During the normal operation, the register 140 may work at high speed. However, the register 140 may operate at low speed during the backup operation. Therefore, during the backup operation, the register 140 needs to be set according to the low speed operation of the non-volatile memory 120. Such setting may be performed at step S311. The module controller 130 may perform the setting of the register 140 for the backup operation through the system management bus SMBUS.

At step S313, the backup operation may be performed. The module controller 130 may read the data of the volatile memory 110 using the volatile memory I/F 220, and store the read data in the non-volatile memory 120 using the non-volatile memory I/F 230.

After the backup operation is completed, the module controller 130 may set the first and second setting values stored in the setting value storage unit 250, to the volatile memory 110 and the register 140 at steps S315 and S317, respectively. The volatile memory 110 and the register 140 may be reset as suitable for the normal operation at a high speed due to steps S315 and S317.

At step S319, the normal operation may be resumed between the memory controller 1 and the volatile memory 110.

Referring to FIG. 3, the module controller 130 may restore the setting values of the volatile memory 110 and the register 140 to their original values for normal operation after completion of the backup operation. Accordingly, the volatile memory 110 and the register 140 may normally communicate with the memory controller 1.

FIG. 4 is a flowchart illustrating the restoration operation of the memory module 130 shown in FIG. 1. The restoration operation may start after the backup operation described with reference to FIG. 3.

At step S401, the memory controller 1 may provide the restoration command for the restoration operation to the module controller 130 through the system management bus SMBUS.

At steps S403 and S405, the module controller 130 in response to the restoration command may perform the same operations as the steps S305 and S307 described with reference to FIG. 3 for backing up the setting value of the volatile memory 110 and the register 140 for the normal operation. When the setting value storage unit 250 keeps the first and second setting values of steps S305 and S307, steps S403 and S405 may be omitted.

At steps S407 and S409, the module controller 130 may set the setting values for the volatile memory 110 and the register 140 such that the volatile memory 110 and the register 140 are suitable for the restoration operation, which is the same as steps S309 and S311 described with reference to FIG. 3 except for the suitability for the backup operation and the restoration operation. Steps S407 and S409 may be performed due to the same reason as steps S309 and S311.

At step S411, the restoration operation may be performed. The module controller 130 may read the data of the non-volatile memory 120 using the non-volatile memory I/F 230 and write the read data in the volatile memory 110 using the volatile memory I/F 220.

After the restoration operation is completed, the module controller 130 at steps S413 and S415 may perform the same operation as the steps S315 and S317 described with reference to FIG. 3. The volatile memory 110 and the register 140 may be reset as suitable for the normal operation at a high speed due to steps S413 and S415.

At step S417, the normal operation may be resumed between the memory controller 1 and the volatile memory 110.

Referring to FIG. 4, the module controller 130 may restore the setting values of the volatile memory 110 and the register 140 to their original values for normal operation after completion of the restoration operation. Accordingly, the volatile memory 110 and the register 140 may normally communicate with the memory controller 1.

In accordance with embodiments of the present invention, the memory module including volatile memory and non-volatile memory may perform the backup and restoration operations as well as the normal operation in response to a command from a host.

Although various embodiments have been described for illustrative purposes, it will be apparent to those skilled in the art that various changes and modifications may be made without departing from the spirit and scope of the invention as defined in the following claims.

What is claimed is:

1. An operation method for a memory module comprising volatile memory, non-volatile memory, and a module controller, comprising:
communicating, by the volatile memory, with a host;
receiving, by the module controller, a backup command from the host;
reading, by the module controller, a setting value of the volatile memory and storing the read setting value as a first storage value;
setting, by the module controller, a setting value suitable for a backup operation in the volatile memory;
performing, by the module controller, the backup operation by storing data stored in the volatile memory in the non-volatile memory;
setting, by the module controller, the first storage value in the volatile memory; and
resuming, by the volatile memory, the communication with the host.

2. The operation method of claim 1,
wherein the memory module further comprises a register suitable for buffering a command and address from the host and transferring the command and address to the volatile memory, and
further comprising:
reading, by the module controller, a setting value of the register and storing the read setting value as a second storage value; and
setting, by the module controller, the setting value suitable for the backup operation in the register between the receiving of the backup command and the performing of the backup operation.

3. The operation method of claim 2, further comprising:
setting, by the module controller, the second storage value in the register between the performing of the backup operation and the resuming of the communication.

4. The operation method of claim 1, further comprising:
after the resuming of the communication,
receiving a restoration command from the host;
setting, by the module controller, a setting value suitable for a restoration operation in the volatile memory;
performing, by the module controller, the restoration operation by storing data stored in the non-volatile memory in the volatile memory; and
setting, by the module controller, the first storage value in the volatile memory.

5. The operation method of claim 3, further comprising:
after the resuming of the communication,
receiving a restoration command from the host;
setting, by the module controller, a setting value suitable or a restoration operation in the volatile memory;
setting, by the module controller, a setting value suitable for the restoration operation in the register;
performing, by the module controller, the restoration operation by storing the data stored in the ion-volatile memory in the volatile memory;
setting, by the module controller, the first storage value in the volatile memory; and
setting, by the module controller, the second storage value in the register.

6. A memory module, comprising:
a volatile memory;
a non-volatile memory; and
a module controller suitable for:
reading a setting value of the volatile memory in response to a backup command from a host;
storing the read setting value as a first storage value;
setting a setting value suitable for a backup operation in the volatile memory;
performing the backup operation by storing data of the volatile memory in the non-volatile memory; and
setting the first storage value in the volatile memory after the backup operation is completed.

7. The memory module of claim 6, wherein the module controller in response to a restoration command from the host, is further suitable for:
setting a setting value suitable for a restoration operation in the volatile memory;
performing the restoration operation by storing the data of the non-volatile memory to the volatile memory; and
setting the first storage value in the volatile memory after the restoration operation is completed.

8. The memory module of claim 6,
further comprising a register suitable for buffering a command and address from the host and transferring the command and address to the volatile memory,
wherein the module controller in response to the backup command is further suitable for:
reading a setting value of the register, and storing the read setting value as a second storage value;
setting the value suitable for the backup operation in the register; and
setting the second storage value in the register after the backup operation is completed.

9. The memory module of claim 7,
further comprising a register suitable for buffering a command and address from the host and transferring the command and address to the volatile memory,
wherein the module controller in response to the backup command is further suitable for:
reading a setting value of the register, and storing the read setting value as a second storage value;
setting the value suitable for the backup operation in the register; and
setting the second storage value in the register after the backup operation is completed, and
wherein the memory module controller in response to the restoration command is further suitable for:
setting the value suitable for the restoration operation in the register; and
setting the second storage value in the register after the restoration operation is completed.

10. The memory module of claim 8,
wherein the memory module controller communicates with the volatile memory through a volatile memory protocol, and
wherein the memory module controller communicates with the register through a system management bus.

11. A module controller of a memory module, comprising:
a volatile memory interface;
a non-volatile memory interface;
a setting value storage unit; and
a control logic suitable for:
reading a setting value of a volatile memory through the volatile memory interface in response to a backup command from a host;
storing the read setting value in the setting value storage unit as a first storage value;
setting a value suitable for a backup operation n the volatile memory through the volatile memory interface;
performing the backup operation by reading data of the volatile memory through the volatile memory interface, and storing the read data in a non-volatile memory through the non-volatile memory interface; and
setting the first storage value stored in the setting value storage unit in the volatile memory through the volatile memory interface after the backup operation is completed.

12. The module controller of claim 11 further comprising:
a system management bus reception unit; and
a system management bus transmission unit,
wherein the control logic in response to the backup co and is further suitable for:
reading a setting value of a register through the system management bus reception unit;
storing the read setting value in the setting value storage unit as a second storage value; and
setting the second storage value stored in the setting value storage unit in the register through the system management bus transmission unit after the backup operation is completed.

13. The module controller of claim 12, wherein the control logic in response to the restoration command is further suitable for:
setting a value suitable for the restoration operation in the volatile memory through the volatile memory interface;
setting the value suitable for the restoration operation in the register through the system management bus transmission unit;
reading the data of the non-volatile memory through the non-volatile memory interface;
storing the read data in the volatile memory through the volatile memory interface;
setting the first storage value stored in the setting value storage unit in the volatile memory through the volatile memory interface after the restoration operation is completed; and
setting the second storage value stored in the setting value storage unit in the register through the system management bus transmission unit.

14. The module controller of claim 12, wherein the backup command is provided through the system management bus reception unit.

15. The module controller of claim 13 wherein the restoration command is provided through the system management bus reception unit.

16. An operation method of a memory module comprising a volatile memory unit and a non-volatile memory unit, the method comprising:
keeping a setting value for a normal operation of the volatile memory unit;
setting the volatile memory unit as suitable for a backup operation;
performing the backup operation by transferring data from the volatile memory unit to the non-volatile memory unit; and
setting the volatile memory unit as suitable for the normal operation by using the kept setting value.

17. An operation method for a memory module comprising a volatile memory unit and a non-volatile memory unit, the method comprising:
keeping a setting value for a normal operation of the volatile memory unit;
setting the volatile memory unit as suitable for a restoration operation;
performing the restoration operation by transferring backed-up data from the non-volatile memory unit to the volatile memory unit; and
setting the volatile memory unit as suitable for the normal operation by using the kept setting value.

18. A memory module comprising:
a volatile memory unit;
a non-volatile memory unit; and
a module controller suitable for:
keeping a setting value for a normal operation of the volatile memory unit;
setting the volatile memory unit as suitable for a backup operation;
performing the backup operation by transferring data from the volatile memory unit to the non-volatile memory unit; and
setting the volatile memory unit as suitable for the normal operation by using the kept setting value.

19. The memory module of claim 18,
wherein the volatile memory unit comprises:
one or more volatile memories; and
a register suitable for buffering and transferring commands and data between an external and the volatile memories, and
wherein the module controller comprises:
a volatile memory interface suitable for transferring commands and data between the module controller and the volatile memories;
a non-volatile memory interface suitable for transferring commands and data between the module controller and the non-volatile memory unit;
a setting value storage unit suitable for keeping the setting value for the normal operation; and
a system management bus unit suitable for transferring command and data between the module controller and the register.

20. A memory module comprising:
a volatile memory unit;
a non-volatile memory unit; and
a module controller suitable for:
keeping a setting value for a normal operation of the volatile memory unit;
setting the volatile memory unit as suitable for a restoration operation;
performing the restoration operation by transferring backed-up data from the non-volatile memory unit to the volatile memory unit; and
setting the volatile memory unit as suitable for the normal operation by using the kept setting value.
